(19) United States
(12) Patent Application Publication
(10) Pub. No.: US 2011/0298139 A1
(43) Pub. Date: Dec. 8, 2011

(54) Semiconductor Package

(76) Inventors: Yi-Shao Lai, Kaohsiung (TW); Tsung-Yueh Tsai, Kaohsiung (TW); Ming-Kun Chen, Kaohsiung (TW); Hsiao-Chuan Chang, Kaohsiung (TW); Ming-Hsiang Cheng, Kaohsiung (TW)

(21) Appl. No.: 12/794,390

(22) Filed: Jun. 4, 2010

(51) Int. Cl. H01L 23/538; H01L 23/52

(52) U.S. Cl. 257/774; 257/773; 257/778; 257/784; 257/E23.169; 257/E23.141

(57) ABSTRACT

The present invention relates to a semiconductor package. The semiconductor package includes a substrate, a first chip and a second chip. The substrate has a first surface, a second surface and at least one through hole. The first chip is disposed adjacent to the first surface of the substrate. The first chip includes a first active surface and a plurality of first signal pads. Part of the first active surface is exposed to the through hole. The position of the first signal pads corresponds to the through hole. The second chip is disposed adjacent to the second surface. The second chip includes a second active surface and a plurality of second signal pads. Part of the second active surface is exposed to the through hole. The position of the second signal pads corresponds to the through hole, and the second signal pads are capacitively coupled to the first signal pads of the first chip, so as to provide proximity communication between the first chip and the second chip. Whereby, the strength of the first chip and the second chip is increased after being mounted to the substrate, so the yield of the semiconductor package is increased.

### BACKGROUND OF THE INVENTION

1. Field of the Invention

The present invention relates to a semiconductor package, and more particularly to a semiconductor package having capacitively coupled signal pads.

2. Description of the Related Art

A new technique referred to as “proximity communication” overcomes the limitations of conductive electrical interconnections by using capacitive coupling to provide communications between two chips. This technique provides higher input/output pads densities than traditional wire-bonding and flip-chip bonding input/output pads (about 100 times greater). To achieve proximity communication, the input/output pads disposed on an active surface of each chip are placed face-to-face with extreme accuracy, and therefore, alignment between the chips is a big challenge. Moreover, the strength of the chip assembly is weak, so the chip assembly cracks easily during being mounted to the substrate.

Therefore, it is necessary to provide a semiconductor package to solve the above problems.

### SUMMARY OF THE INVENTION

The present invention is directed to a semiconductor package. The semiconductor package comprises a substrate, a first chip and a second chip. The substrate has a first surface, a second surface and at least one through hole. The second surface is opposite the first surface, and the through hole penetrates the substrate. The first chip is disposed adjacent to the first surface of the substrate. The first chip comprises a first active surface and a plurality of first signal pads. Part of the first active surface is exposed to the through hole. The position of the first signal pads corresponds to the through hole. The second chip is disposed adjacent to the second surface. The second chip comprises a second active surface and a plurality of second signal pads. Part of the second active surface is exposed to the through hole. The position of the second signal pads corresponds to the through hole, and the second signal pads are capacitively coupled to the first signal pads of the first chip, so as to provide proximity communication between the first chip and the second chip.

Whereby, the first chip and the second chip are mounted to the substrate and the through hole enables the first signal pads and the second signal pads to provide proximity communication between the first chip and the second chip. Therefore, the strength of the first chip and the second chip is increased after being mounted to the substrate, so the yield of the semiconductor package is increased.

The present invention is further directed to a semiconductor package. The semiconductor package comprises a substrate, a first chip and a second chip. The substrate has a first surface, a second surface, a plurality of third signal pads and a plurality of fourth signal pads. The second surface is opposite the first surface. The third signal pads are disposed adjacent to the first surface. The fourth signal pads are disposed adjacent to the second surface. The first chip is disposed adjacent to the first surface of the substrate. The first chip comprises a first active surface and a plurality of first signal pads. The first active surface faces the first surface of the substrate. The first signal pads are capacitively coupled to the third signal pads of the substrate, so as to provide proximity communication between the first chip and the substrate. The second chip is disposed adjacent to the second surface of the substrate. The second chip comprises a second active surface and a plurality of second signal pads. The second active surface faces the second surface of the substrate. The second signal pads are capacitively coupled to the fourth signal pads of the substrate, so as to provide proximity communication between the second chip and the substrate.

Whereby, the substrate acts as a coupling interface between the first chip and the second chip, so that the first signal pads of the first chip do not have to align with the second signal pads of the second chip, and the first chip and the second chip have more flexibility in pad design. Therefore, the yield rate of the semiconductor package is increased.

The present invention is further directed to a semiconductor package. The semiconductor package comprises a substrate, a first chip and a second chip. The substrate has a first surface, a second surface, a plurality of first input/output pads, a plurality of second input/output pads, a plurality of third signal pads and a plurality of fourth signal pads. The second surface is opposite the first surface. The first input/output pads are disposed on the first surface. The second input/output pads are disposed on the second surface. The third signal pads and the fourth signal pads are disposed between the first input/output pads and the second input/output pads. The third signal pads are electrically connected to the first input/output pads through direct electrical connections. The fourth signal pads are electrically connected to the second input/output pads through direct electrical connections. The fourth signal pads are capacitively coupled to the third signal pads to provide proximity communication therebetween.

The first chip is disposed adjacent to the first surface of the substrate. The first chip comprises a first active surface, a plurality of first signal pads, a first transmitter circuit and a first receiver circuit. The first active surface faces the first surface of the substrate, and the first signal pads are electrically connected to the first input/output pads of the substrate. The second chip is disposed adjacent to the second surface of the substrate. The second chip comprises a second active surface, a plurality of second signal pads, a second transmitter circuit and a second receiver circuit. The second active surface faces the second surface of the substrate, and the second signal pads are electrically connected to the second input/output pads of the substrate.

Whereby, the signal pads of the substrate increase the ability of transmitting a high-speed signal, and enable a conventional wire-bonding or flip-chip bonding chip to be applied in the semiconductor package.

### BRIEF DESCRIPTION OF THE DRAWINGS

FIGS. 1 to 4 are schematic views of a method for making a semiconductor package according to a first embodiment of the present invention;

FIG. 5 is a partially enlarged cross-sectional view of FIG. 4;

FIG. 6 is a cross-sectional view of a semiconductor package according to a second embodiment of the present invention;

FIG. 7 is a cross-sectional view of a semiconductor package according to a third embodiment of the present invention;

FIG. 8 is a cross-sectional view of a semiconductor package according to a fourth embodiment of the present invention; and

FIG. 9 is a cross-sectional view of a semiconductor package according to a fifth embodiment of the present invention.

### DETAILED DESCRIPTION OF THE INVENTION

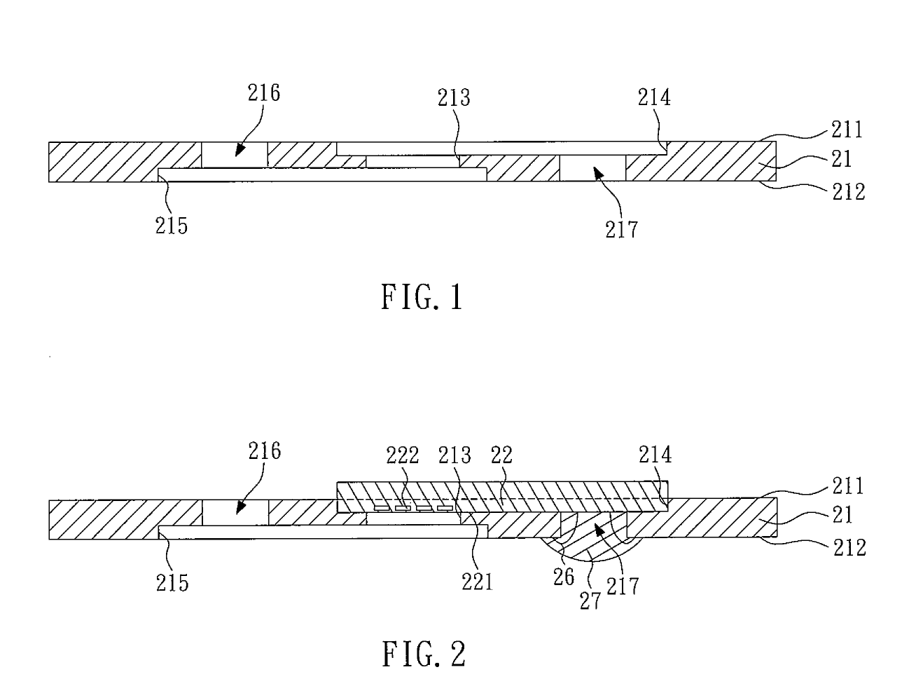

FIGS. 1 to 4 show schematic views of a method for making a semiconductor package according to a first embodiment of the present invention. As shown in FIG. 1, a substrate 21 is provided. The substrate 21 has a first surface 211, a second surface 212 and at least one through hole 213. In the embodiment, the substrate 21 further comprises a first cavity 214, a second cavity 215, a first window 216 and a second window 217. The second surface 212 is opposite the first surface 211. The through hole 213 penetrates the substrate 21. The first cavity 214 opens at the first surface 211. The second cavity 215 opens at the second surface 212, and the through hole 213 communicates with the first cavity 214 and the second cavity 215. The first window 216 and the second window 217 penetrate the substrate 21.

As shown in FIG. 2, a first chip 22 is disposed adjacent to the first surface 211 of the substrate 21, and preferably, the first chip 22 is disposed in the first cavity 214 of the substrate 21. The first chip 22 comprises a first active surface 221 and a plurality of first signal pads 222. Part of the first active surface 221 is exposed to the through hole 213. The position of the first signal pads 222 corresponds to the through hole 213. The first window 216 exposes part of the first active surface 221 of the first chip 22 for wire-bonding. Then, a plurality of bonding wires 26 are formed to electrically connect the first chip 22 and the substrate 21, and a molding material 27 is formed to encapsulate the bonding wires 26. Therefore, the first chip 22 is electrically connected to the substrate 21 by wire-bonding.

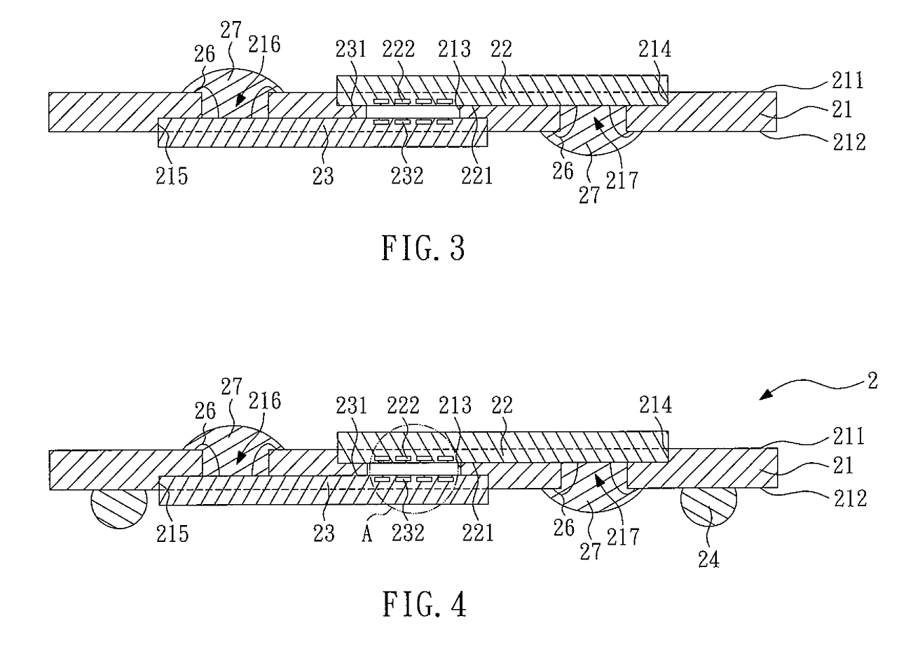

As shown in FIG. 3, a second chip 23 is disposed adjacent to the second surface 212, and preferably, the second chip 23 is disposed in the second cavity 215. The second chip 23 comprises a second active surface 231 and a plurality of second signal pads 232. Part of the second active surface 231 is exposed to the through hole 213. The position of the second signal pads 232 corresponds to the through hole 213, and the second signal pads 232 are capacitively coupled to the first signal pads 222 of the first chip 22, so as to provide proximity communication between the first chip 22 and the second chip 23. The second window 217 exposes part of the second active surface 231 of the second chip 23 for wire-bonding. Then, the bonding wires 26 are formed to electrically connect the second chip 23 and the substrate 21, and the molding material 27 is formed to encapsulate the bonding wires 26. Therefore, the second chip 23 is electrically connected to the substrate 21 by wire-bonding. As shown in FIG. 4, a plurality of solder balls 24 are disposed on the second surface 212 of the substrate 21 for establishing external electrical connection.

FIG. 4 shows a cross-sectional view of a semiconductor package according to the first embodiment of the present invention. The semiconductor package 2 comprises a substrate 21, a first chip 22 and a second chip 23. In the embodiment, the semiconductor package 2 further comprises a plurality of solder balls 24, a plurality of bonding wires 26 and a molding material 27. The substrate 21 has a first surface 211, a second surface 212 and at least one through hole 213. In the embodiment, the substrate 21 further comprises a first cavity 214, a second cavity 215, a first window 216 and a second window 217. The second surface 212 is opposite the first surface 211. The through hole 213 penetrates the substrate 21 and communicates with the first cavity 214 and the second cavity 215. The first cavity 214 opens at the first surface 211, and the first chip 22 is disposed in the first cavity 214. The second cavity 215 opens at the second surface 212, and the second chip 23 is disposed in the second cavity 215. The first window 216 and the second window 217 penetrate the substrate 21 and expose part of the first chip 22 and part of the second chip 23 for wire-bonding.

The first chip 22 is disposed adjacent to the first surface 211 of the substrate 21. The first chip 22 comprises a first active surface 221 and a plurality of first signal pads 222. Part of the first active surface 221 is exposed to the through hole 213. The position of the first signal pads 222 corresponds to the through hole 213. The second chip 23 is disposed adjacent to the second surface 212. The second chip 23 comprises a second active surface 231 and a plurality of second signal pads 232. Part of the second active surface 231 is exposed to the through hole 213. The position of the second signal pads 232 corresponds to the through hole 213, and the second signal pads 232 are capacitively coupled to the first signal pads 222 of the first chip 22, so as to provide proximity communication between the first chip 22 and the second chip 23.

In the embodiment, the first chip 22 and the second chip 23 are electrically connected to the substrate 21 by wire-bonding, that is, the first chip 22 and the second chip 23 are electrically connected to the substrate 21 by the bonding wires 26, and the molding material 27 encapsulates the bonding wires 26. The solder balls 24 are disposed on the second surface 212 of the substrate 21 for establishing external electrical connection.

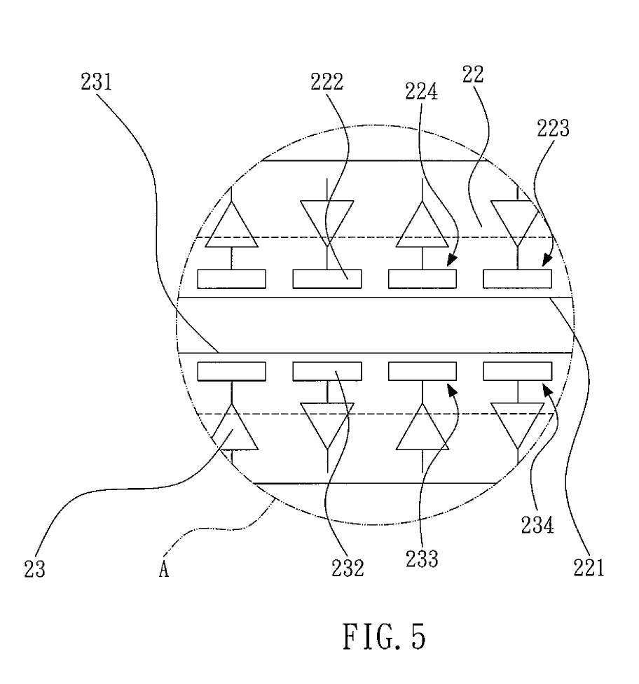

As shown in FIG. 5, the first signal pads 222 of the first chip 22 comprise a plurality of first transmitter pads 223 and a plurality of first receiver pads 224, the second signal pads 232 of the second chip 23 comprise a plurality of second transmitter pads 233 and a plurality of second receiver pads 234, the first transmitter pads 223 are aligned with the second receiver pads 234, and the first receiver pads 224 are aligned with the first receiver pads 233.

It should be noted that the first chip 22 and the second chip 23 communicate with each other through proximity communication between the first signal pads 222 and the second signal pads 232, instead of direct electrical connections; however, electrical power or ground is transmitted between the first chip 22 and the second chip 23 through direct electrical connections, e.g., bonding wires 26.

Proximity communication replaces resistance bonding wires by communicating through capacitive coupling between the first chip 22 and the second chip 23, promises significant increase in communications speed in an electronic system. Comparing traditional area ball bonding, proximity communication has one order smaller scale, so it can be two order denser (in terms of connection number/pin number) than ball bonding. This technique to requires very good alignment and very small gaps between the first chip 22 and the second chip 23 (under 10 micrometers) for face-to-face placement.

In order to achieve the function of proximity communication, part of the first chip 22 and the second chip 23 are placed face-to-face in a manner that aligns the transmitter circuit with the receiver circuit in extremely close proximity, for example, with only microns of separation between them. The signals between the transmitter circuit and the receiver circuit may be transmitted by inductive or capacitive coupling with low overall communication cost.

Take transmission by capacitive coupling for example. The first signal pads 222 of the first chip 22 and the second signal pads 232 of the second chip 23 are aligned with each other. Since the first signal pads 222 and the second signal pads 232 are not in physical contact with each other, there are capacitances between the first signal pads 222 of the first chip 22 and the second signal pads 232 of the second chip 23. It is this capacitive coupling that provides signal paths between the first chip 22 and the second chip 23. Changes in the electrical potential of the first signal pads 222 of the first chip 22 cause corresponding changes in the electrical potential of the corresponding second signal pads 232 of the second chip 23. Suitable drivers of the transmitter circuit and sensing circuits of the receiver circuit in the first chip 22 and the second chip 23 make communication through this small capacitance possible.

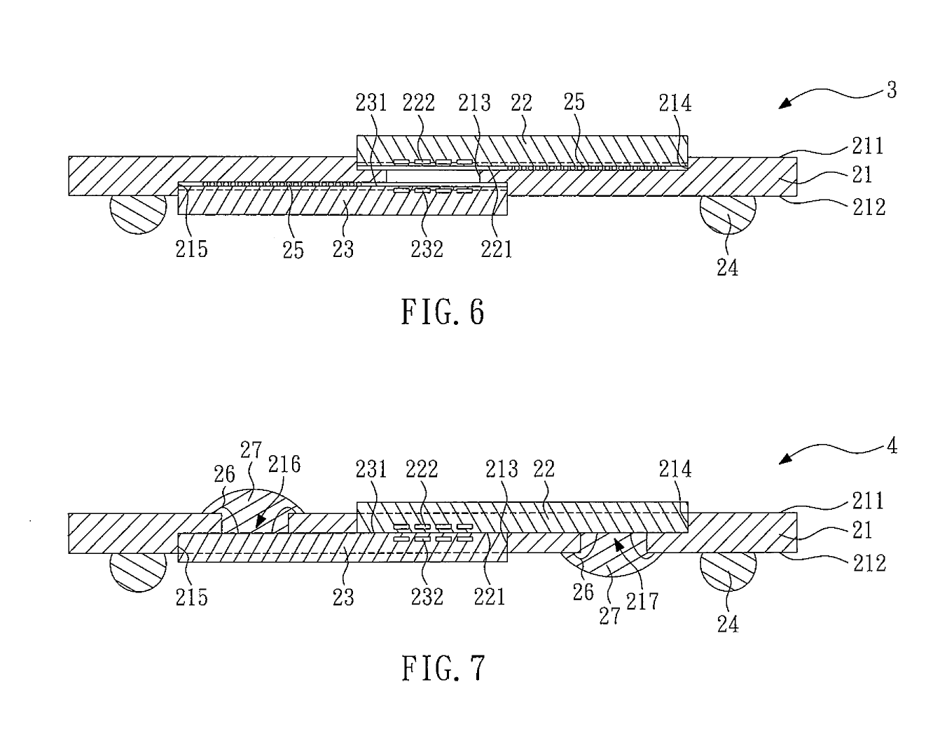

FIG. 6 shows a cross-sectional view of a semiconductor package according to a second embodiment of the present invention. The semiconductor package 3 according to the second embodiment is substantially the same as the semiconductor package 2 (FIG. 2) according to the first embodiment, and the same elements are designated by the same reference numbers. The difference between the semiconductor package 3 and the semiconductor package 2 (FIG. 2) is that the semiconductor package 3 further comprises a plurality of bumps 25, and does not comprise the bonding wires 26 and the molding material 27. The substrate 21 does not comprise the first window 216 and the second window 217. In the embodiment, the first chip 22 and the second chip 23 are electrically connected to the substrate 21 by flip-chip bonding, that is, the first chip 22 and the second chip 23 are electrically connected to the substrate 21 by the bumps 25. It should be noted that the first chip 22 and the second chip 23 communicate with each other through proximity communication between the first signal pads 222 and the second signal pads 232, instead of direct electrical connections; however, electrical power or ground is transmitted between the first chip 22 and the second chip 23 through bumps 25.

FIG. 7 shows a cross-sectional view of a semiconductor package according to a third embodiment of the present invention. The semiconductor package 4 according to the third embodiment is substantially the same as the semiconductor package 3 (FIG. 6) according to the second embodiment, and the same elements are designated by the same reference numbers. The difference between the semiconductor package 4 and the semiconductor package 3 (FIG. 6) is that the first cavity 214 directly communicates with the second cavity 215. Therefore, the first active surface 221 of the first chip 22 directly contacts the second active surface 231 of the second chip 23, and the first signal pads 222 and the second signal pads 232 are spaced by a passivation layer (not shown) formed thereon.

The first chip 22 and the second chip 23 are mounted to the substrate 21 and the through hole 213 enables the first signal pads 222 and the second signal pads 232 to provide proximity communication between the first chip 22 and the second chip 23. Therefore, the strength of the first chip 22 and the second chip 23 is increased after being mounted to the substrate 21, so the yield of the semiconductor package 2 is increased.

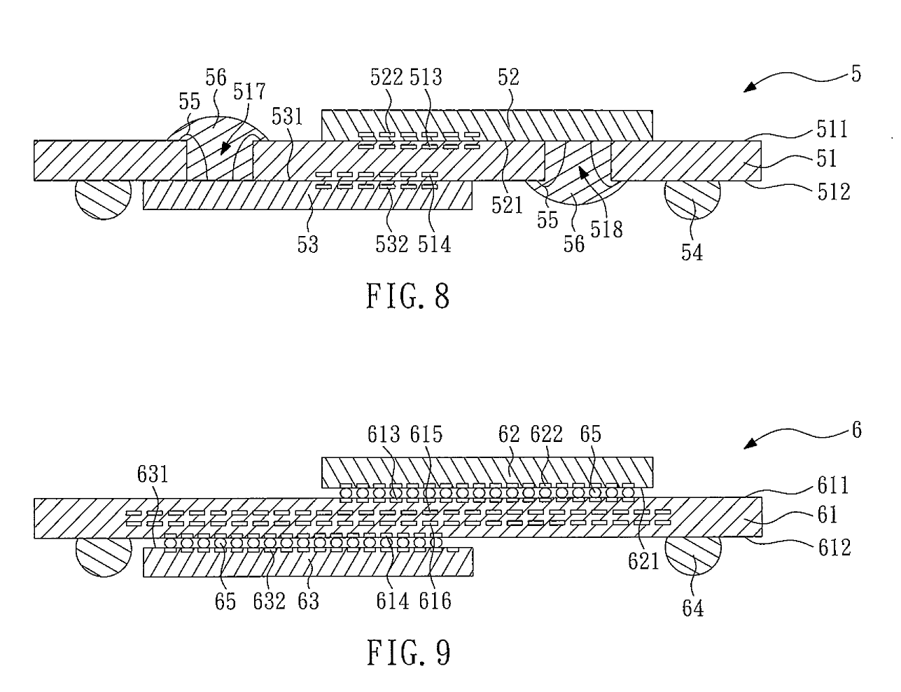

FIG. 8 shows a cross-sectional view of a semiconductor package according to a fourth embodiment of the present invention. The semiconductor package 5 comprises a substrate 51, a first chip 52 and a second chip 53. In the embodiment, the semiconductor package 5 further comprises a plurality of solder balls 54, a plurality of bonding wires 55 and a molding material 56. The substrate 51 has a first surface 511, a second surface 512, a plurality of third signal pads 513 and a plurality of fourth signal pads 514. In the embodiment, the substrate 51 further comprises a first window 517 and a second window 518.

The second surface 512 is opposite the first surface 511. The third signal pads 513 are disposed adjacent to the first surface 511. The fourth signal pads 514 are disposed adjacent to the second surface 512. In the embodiment, the fourth signal pads 514 are electrically connected to the third signal pads 513 through conductive traces and vias (not shown) built in the substrate 51, respectively. In the embodiment, the first window 517 penetrates the substrate 51 and exposes part of the first chip 52 for wire-bonding, and the second window 518 penetrates the substrate 51 and exposes part of the second chip 53 for wire-bonding.

The first chip 52 is disposed adjacent to the first surface 511 of the substrate 51. The first chip 52 comprises a first active surface 521 and a plurality of first signal pads 522. The first active surface 521 faces the first surface 511 of the substrate 51. The first signal pads 522 are capacitively coupled to the third signal pads 513 of the substrate 51, so as to provide proximity communication between the first chip 52 and the substrate 51.

The second chip 53 is disposed adjacent to the second surface 512 of the substrate 51. The second chip 53 comprises a second active surface 531 and a plurality of second signal pads 532. The second active surface 531 faces the second surface 512 of the substrate 51. The second signal pads 532 are capacitively coupled to the fourth signal pads 514 of the substrate 51, so as to provide proximity communication between the second chip 53 and the substrate 51.

The first signal pads 522 of the first chip 52 comprise a plurality of first transmitter pads (not shown) and a plurality of first receiver pads (not shown), the second signal pads 532 of the second chip 53 comprise a plurality of second transmitter pads (not shown) and a plurality of second receiver pads (not shown), the third signal pads 513 of the substrate 51 comprise a plurality of third transmitter pads (not shown) and a plurality of third receiver pads (not shown), the fourth signal pads 514 of the substrate 51 comprise a plurality of fourth transmitter pads (not shown) and a plurality of fourth receiver pads (not shown). The first transmitter pads are aligned with the third receiver pads, the third receiver pads are aligned with the first receiver pads. The second transmitter pads are aligned with the fourth receiver pads, and the fourth receiver pads are aligned with the second receiver pads.

The first chip 52 and the second chip 53 are electrically connected to the substrate 51 by wire-bonding, that is, the first chip 52 and the second chip 53 are electrically connected to the substrate 51 by the bonding wires 55, and the molding material 56 encapsulates the bonding wires 55. However, in other applications, the first chip 52 and the second chip 53 can be electrically connected to the substrate 51 by flip-chip bonding. The solder balls 54 are disposed on the second surface 512 of the substrate 51 for establishing external electrical connection.

Since the substrate 51 acts as a coupling interface between the first chip 52 and the second chip 53, the first signal pads 522 of the first chip 52 do not have to align with the second signal pads 532 of the second chip 53, and therefore the first chip 52 and the second chip 53 have more flexibility in pad design. Therefore, the yield rate of the semiconductor package 5 is increased.

FIG. 9 shows a cross-sectional view of a semiconductor package according to a fifth embodiment of the present invention. The semiconductor package 6 comprises a substrate 61, a first chip 62 and a second chip 63. In the embodiment, the semiconductor package 6 further comprises a plurality of solder balls 64 and a plurality of bumps 65. The substrate 61 has a first surface 611, a second surface 612, a plurality of first input/output pads 613, a plurality of second input/output pads 614, a plurality of third signal pads 615 and a plurality of fourth signal pads 616.

The second surface 612 is opposite the first surface 611. The first input/output pads 613 are disposed on the first surface 611. The second input/output pads 614 are disposed on the second surface 612. The third signal pads 615 and the fourth signal pads 616 are disposed between the first input/output pads 613 and the second input/output pads 614. The third signal pads 615 are electrically connected to the first input/output pads 613, and the fourth signal pads 616 are electrically connected to the second input/output pads 614 through conductive traces and vias (not shown) built in the substrate 61. It should be noted that the third signal pads 615 and the fourth signal pads 616 communicate with each other through proximity communication therebetween, instead of direct electrical connections, e.g., conventional conductive trace or via. Since the third signal pads 615 and the fourth signal pads 616 are not in physical contact with each other, there are capacitances therebetween. It is this capacitive coupling that provides signal paths between the third signal pads 615 and the fourth signal pads 616.

The third signal pads 615 of the substrate 61 comprise a plurality of third transmitter pads (not shown) and a plurality of third receiver pads (not shown), the fourth signal pads 616 of the substrate 61 comprise a plurality of fourth transmitter pads (not shown) and a plurality of fourth receiver pads (not shown). The third transmitter pads are aligned with the fourth receiver pads, and the fourth receiver pads are aligned with the third receiver pads.

It should be noted that the substrate 61 is still provided with conventional conductive traces and vias for transmitting signals between the first chip 62 and the second chip 63 as well as outside environment.

The first chip 62 is disposed adjacent to the first surface 611 of the substrate 61. The first chip 62 comprises a first active surface 621, a plurality of first signal pads 622, a first transmitter circuit (not shown) and a first receiver circuit (not shown). The first active surface 621 faces the first surface 611 of the substrate 61, and the first signal pads 622 are electrically connected to the first input/output pads 613 of the substrate 61.

The second chip 63 is disposed adjacent to the second surface 612 of the substrate 61. The second chip 63 comprises a second active surface 631, a plurality of second signal pads 632, a second transmitter circuit and a second receiver circuit. The second active surface 631 faces the second surface 612 of the substrate 61, and the second signal pads 632 are electrically connected to the second input/output pads 614 of the substrate 61.

In the embodiment, the first chip 62 and the second chip 63 are electrically connected to the substrate 61 by flip-chip bonding, that is, the first chip 62 and the second chip 63 are electrically connected to the substrate 61 by the bumps 65. However, in other applications, the first chip 62 and the second chip 63 can be electrically connected to the substrate 61 by wire-bonding. The solder balls 64 are disposed on the second surface 612 of the substrate 61 for establishing external electrical connection.

Suitable drivers of the transmitter circuit and sensing circuits of the receiver circuit in the first chip 62 and the second chip 63 make communication through this small capacitance possible. Specifically, the first transmitter circuit of the first chip 62 feeds a signal to a capacitive transmitter region, i.e., the third signal pads 615 in the substrate 61. The signal is capacitively transmitted to capacitive receiver region, i.e., the fourth signal pads 616 and passes into the second receiver circuit of the second chip 63.

The signal pads 615, 616 of the substrate 61 increase the ability of transmitting a high-speed signal, and enable a conventional wire-bonding or flip-chip bonding chip (the first chip 62 and the second chip 63) to be applied in the semiconductor package 6.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined by the appended claims.

What is claimed is:

1. A semiconductor package, comprising:
a substrate, having a first surface, a second surface and at least one through hole, wherein the second surface is opposite the first surface, and the through hole penetrates the substrate;
a first chip, disposed adjacent to the first surface of the substrate, wherein the first chip comprises a first active surface and a plurality of first signal pads, part of the first active surface is exposed to the through hole, the position of the first signal pads corresponds to the through hole; and
a second chip, disposed adjacent to the second surface, wherein the second chip comprises a second active surface and a plurality of second signal pads, part of the second active surface is exposed to the through hole, the position of the second signal pads corresponds to the through hole, and the second signal pads are capacitively coupled to the first signal pads of the first chip, so as to provide proximity communication between the first chip and the second chip.

2. The semiconductor package as claimed in claim 1, wherein the substrate further comprises a first cavity and a second cavity, the first cavity opens at the first surface, the second cavity opens at the second surface, the through hole communicates with the first cavity and the second cavity, the first chip is disposed in the first cavity, and the second chip is disposed in the second cavity.

3. The semiconductor package as claimed in claim 2, wherein the first active surface of the first chip directly contacts the second active surface of the second chip, and the first signal pads and the second signal pads are spaced apart from each other.

4. The semiconductor package as claimed in claim 1, wherein the first chip and the second chip are electrically connected to the substrate by flip-chip bonding.

5. The semiconductor package as claimed in claim 1, wherein the substrate further comprises a first window and a second window, the first window penetrates the substrate and exposes part of the first active surface of the first chip for wire-bonding, and the second window penetrates the substrate and exposes part of the second active surface of the second chip for wire-bonding.

6. The semiconductor package as claimed in claim 1, wherein the first signal pads of the first chip comprise a plurality of first transmitter pads and a plurality of first receiver pads, the second signal pads of the second chip comprise a plurality of second transmitter pads and a plurality of second receiver pads, the first transmitter pads are aligned with the second receiver pads, and the first receiver pads are aligned with the first receiver pads.

7. A semiconductor package, comprising:
a substrate, having a first surface, a second surface, a plurality of third signal pads and a plurality of fourth signal pads, wherein the second surface is opposite the first surface, the third signal pads are disposed adjacent to the first surface, the fourth signal pads are disposed adjacent to the second surface and electrically connected to the third signal pads;
a first chip, disposed adjacent to the first surface of the substrate, wherein the first chip comprises a first active surface and a plurality of first signal pads, the first active surface faces the first surface of the substrate, the first signal pads are capacitively coupled to the third signal pads of the substrate, so as to provide proximity communication between the first chip and the substrate; and
a second chip, disposed adjacent to the second surface of the substrate, wherein the second chip comprises a second active surface and a plurality of second signal pads, the second active surface faces the second surface of the substrate, the second signal pads are capacitively coupled to the fourth signal pads of the substrate, so as to provide proximity communication between the second chip and the substrate.

8. The semiconductor package as claimed in claim 7, wherein the first chip and the second chip are electrically connected to the substrate by flip-chip bonding.

9. The semiconductor package as claimed in claim 7, wherein the substrate further comprises a first window and a second window, the first window penetrates the substrate and exposes part of the first active surface of the first chip for wire-bonding, and the second window penetrates the substrate and exposes part of the second active surface of the second chip for wire-bonding.

10. The semiconductor package as claimed in claim 7, wherein the first signal pads of the first chip comprise a plurality of first transmitter pads and a plurality of first receiver pads, the second signal pads of the second chip comprise a plurality of second transmitter pads and a plurality of second receiver pads, the third signal pads of the substrate comprise a plurality of third transmitter pads and a plurality of third receiver pads, the fourth signal pads of the substrate comprise a plurality of fourth transmitter pads and a plurality of fourth receiver pads, the first transmitter pads are aligned with the third receiver pads, the third receiver pads are aligned with the first receiver pads, the second transmitter pads are aligned with the fourth receiver pads, and the fourth receiver pads are aligned with the second receiver pads.

11. A semiconductor package, comprising:
a substrate, having a first surface, a second surface, a plurality of first input/output pads, a plurality of second input/output pads, a plurality of third signal pads and a plurality of fourth signal pads, wherein the second surface is opposite the first surface, the first input/output pads are disposed on the first surface, the second input/output pads are disposed on the second surface, the third signal pads and the fourth signal pads are disposed between the first input/output pads and the second input/output pads, the third signal pads are electrically connected to the first input/output pads through direct electrical connections, and the fourth signal pads are electrically connected to the second input/output pads through direct electrical connections, and the fourth signal pads are capacitively coupled to the third signal pads to provide proximity communication therebetween;
a first chip, disposed adjacent to the first surface of the substrate, wherein the first chip comprises a first active surface, a plurality of first signal pads, a first transmitter circuit and a first receiver circuit, the first active surface faces the first surface of the substrate, and the first signal pads are electrically connected to the first input/output pads of the substrate; and
a second chip, disposed adjacent to the second surface of the substrate, wherein the second chip comprises a second active surface, a plurality of second signal pads, a second transmitter circuit and a second receiver circuit, the second active surface faces the second surface of the substrate, and the second signal pads are electrically connected to the second input/output pads of the substrate.

12. The semiconductor package as claimed in claim 11, wherein the first chip and the second chip are electrically connected to the substrate by flip-chip bonding or wire-bonding.

13. The semiconductor package as claimed in claim 11, further comprising a plurality of solder balls, the solder balls are disposed on the second surface of the substrate.

14. The semiconductor package as claimed in claim 11, wherein the first transmitter circuit of the first chip feeds a signal to the third signal pads in the substrate, the signal is capacitively transmitted to the fourth signal pads and passes into the second receiver circuit of the second chip.

15. The semiconductor package as claimed in claim 11, wherein the third signal pads of the substrate comprise a plurality of third transmitter pads and a plurality of third receiver pads, the fourth signal pads of the substrate comprise a plurality of fourth transmitter pads and a plurality of fourth receiver pads, the third transmitter pads are aligned with the fourth receiver pads, and the fourth receiver pads are aligned with the third receiver pads.
